(19) United States
(12) Patent Application Publication
(10) Pub. No.: US 2012/0153116 A1
(43) Pub. Date: Jun. 21, 2012

(54) Convertible Case for a Tablet Computer

(76) Inventor: Doug Harrison, Tower City, PA (US)

(21) Appl. No.: 13/169,716

(22) Filed: Jun. 27, 2011

Related U.S. Application Data
(60) Provisional application No. 61/358,689, filed on Jun. 25, 2010.

(51) Int. Cl. A47B 97/04; H05K 5/00; B65D 85/00

(52) U.S. Cl. 248/460; 206/320

(57) ABSTRACT

A convertible case for a tablet computer comprising a first panel, a second panel, at least one semi-rigid support flap. Said first and second panels are joined and foldable along an axis, such that said first and second panels are aligned back-to-back, wherein the interior face of the first panel and the interior face of the second panel are directed outwards in opposite directions.

The first panel is defined by an interior face and an exterior face, said interior face adapted to securely hold a tablet computer on the interior face.

The second panel is defined by an interior face having a fabric layer covering a substantial portion of said inferior face with an opening adapted to receive a user's hand, such that when a user's hand is placed in the opening, the user's hand is snugly held in place between the interior face and the fabric layer.

### RELATED APPLICATION

The application claims priority of provisional patent application Ser. No. 61/358,689 filed Jun. 25, 2010.

### FIELD OF THE INVENTION

The present invention relates to a carrying case for a tablet computer that offers protection for the personal tablet computer. The case can also be converted to serve as a work station in three distinct arrangements. In two of the modes the workstation can be rested in various position on a support surface such as a desk or tabletop, in the other mode, the workstation is secured, glove-like, to the user's hand to allow easy access, manipulation, and display of the tablet computer screen while the user is holding the device.

### BACKGROUND OF THE INVENTION

Tablet computers are becoming more popular and there is a demand for convenient carrying cases which offer easy access as well as protection for the computer. A tablet computer has touchscreen technology which allows the user to operate the computer with a stylus or digital pen, or a fingertip, instead of a keyboard or mouse. Traditional protective cases have not offered the versatility to convert the carrying case into a portable hand-held workstation, for easy on-the-go use, as well as simple presentation and sharing ability.

### SUMMARY OF THE INVENTION

According to the present invention, a carrying case for a tablet computer is made more useful by providing the case with a convertible “folder-like” two-sided design. The tablet computer can safely slide in and out of the case, and be easily secured to one interior side of case for easy storage and travel, and when the user wishes to use the device, whether on-the-go or at a surface, such as a desk or table, the case is easily converted to a workstation.

The interior of one of the two sides of the case holds the tablet computer in place (See FIGS. 1, 2 & 6-9). The interior of the other side serves as a protective cover when the case is closed (See FIGS. 1 and 2), serves as a support for upright use on a surface (See FIGS. 7-9), and also has an opening for a hand, which serves as the handle/glove for on-the-go display and use (see FIGS. 5 and 6).

In the preferred embodiment, The case has at least one additional rigid support flap, as shown in FIGS. 3, and 7 through 9, used to support the display screen an upright viewing position. When secured upright, the tablet and case can be rested horizontally or vertically to allow for portrait or landscape display of the tablet screen. Additionally the rigid support surface has multiple connection points, so that the angle of the opening can be reduced, so that the case can used lying down, with the screen angled up, ideal for use with a keyboard as shown in FIG. 9.

The opening for the user's hand is located on the interior of the second side, and is ideally centered, and symmetrical. By centering a symmetrical opening, the device can be freely rotated a full 360° to allow for easy use at any angle. When the second side is folded-back, it can be secured to the opposite side by any basic attachment means such as a basic hook and loop device, as shown in FIG. 4. When folded back, the opening is on the opposite outward-facing side as the tablet screen. A user then slides a hand into the opening, allowing for the easy and fully open presentation and access to the tablet computer screen. The device is easily supported in one hand, leaving the other hand free to operate the tablet computer while maintaining a full range of motion and full display of the screen, great for sharing content with others, for example in a meeting-type setting.

### BRIEF DESCRIPTION OF THE DRAWINGS

The attached figures illustrate a convertible case for a tablet computer according to the present invention:

FIG. 1 illustrates the interior of one embodiment of the convertible case for a tablet computer of the present invention in the open position;

FIG. 2 illustrates the interior of an embodiment of the convertible case for a tablet computer of the present invention in the open position, with a tablet computer secured to one interior side;

FIG. 3 illustrates the exterior of an embodiment of the convertible case for a tablet computer of the present invention in the open position;

FIG. 4 illustrates the rear-face of an embodiment of the convertible case for a tablet computer of the present invention in the folded-back display position;

FIG. 5 illustrates the rear-face of an embodiment of the convertible case for a tablet computer of the present invention in the folded-back display position, while in use;

FIG. 6 illustrates the front-face of an embodiment of the convertible case for a tablet computer of the present invention in the folded-back display position, while in use;

FIG. 7 illustrates an embodiment of the convertible case for a tablet computer of the present invention in the upright display position, with the tablet computer aligned in a landscape position;

FIG. 8 illustrates an embodiment of the convertible case for a tablet computer of the present invention in the upright display position, with the tablet computer aligned in a portrait position; and

FIG. 9 illustrates an embodiment of the convertible case for a tablet computer of the present invention in the typing display position.

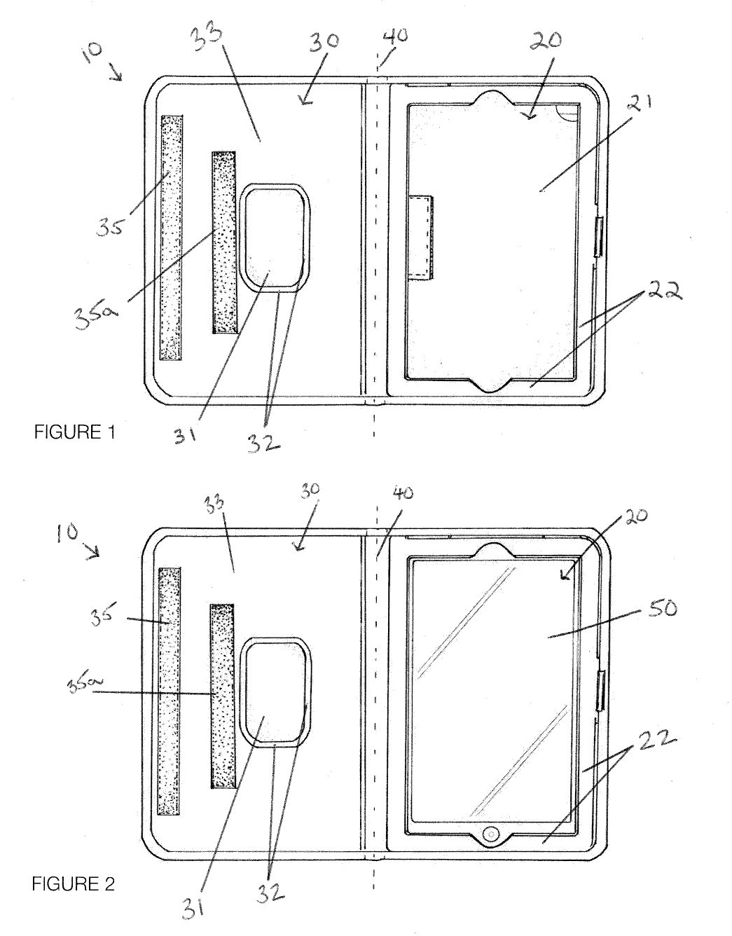

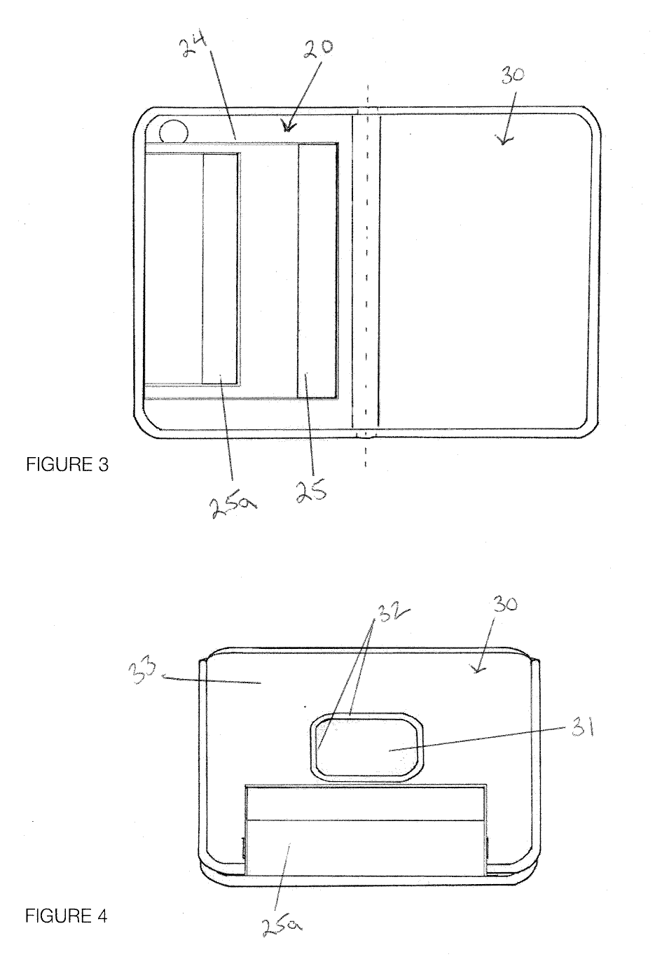

### DETAILED DESCRIPTION OF THE DRAWINGS

A convertible case for a tablet computer (10) has two substantially rigid main panels, a first panel (20), which is a tablet computer support panel, designed to securely hold tablet computer (50), and a second panel (30), which has varying functions depending on its orientation.

The interior side of the first panel (20) has a means for securing a tablet computer (50) to the interior face (21) of first panel (20). In the preferred embodiment, said securing means is a perimeter border (22) adapted to secure a tablet computer (50) between interior face (21) and the perimeter border (22), without interfering with the screen of the tablet computer (50). It should be understood that the perimeter border (22) can be a continuos border around the entire perimeter, or it can be a plurality of clips that can latch down along multiple sides of the tablet computer (50).

First Panel (20) and second panel (30) are connected and foldable, in both directions, along axis (40). Second panel (30) can be folded into a closed position like a traditional folder or case, such that second panel (30) covers and protects the tablet computer (50) that is secured to the First panel (20). As such, the case acts as a traditional case, ideal for protecting the tablet computer (50) during storage and transport. In such a configuration, second panel (30) covers the tablet computer (50), and accordingly, the tablet computer (50) cannot be used in this position; this configuration is ideal for storage and transport only.

The present invention, allows second panel (30) to be folded back into a variety of open-display positions, allowing the tablet computer to be optimally used while stored in the case. Additionally, the interior face (31) of the second panel (30) contains at least one securing mechanism (35 and 35a), such as the receiving end for a traditional snap, or one half of a traditional hook and loop device. In the preferred embodiment, the interior face (31) has two strips (35 and 35a) that serve as the receiving side of a hook and loop connection. The exterior side (24) of first panel (20) includes at least one semi-rigid flap (25 and 25a). One side of each of the semi-rigid flaps (25 and 25a) contains the mating half of the securing mechanism (35 and 35a), such as the securing end for a traditional snap, or hook and loop device. The semi-rigid flap (25 and 25a) can thus be secured to the securing mechanism (35 and 35a). Additional semi-rigid flaps (25 and 25a), along with additional securing mechanisms (35 and 35a) allow for more display options or “modes.”

For instance, the preferred embodiment, as shown in the Figures has three modes:

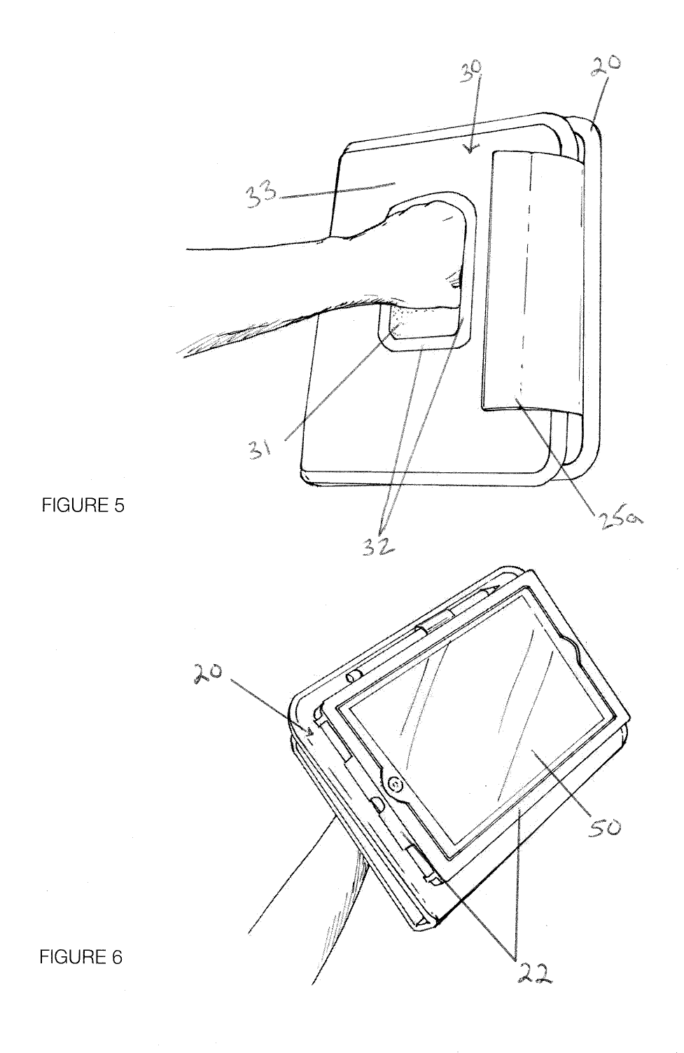

A first “presentation” mode is shown in FIGS. 4 through 6. In this mode, the shorter rigid flap (25a) is secured to the interior securing mechanism (35a), and, as shown in FIG. 4, the second panel (30) is folded completely back, to form a substantially flat rectangular support and display.

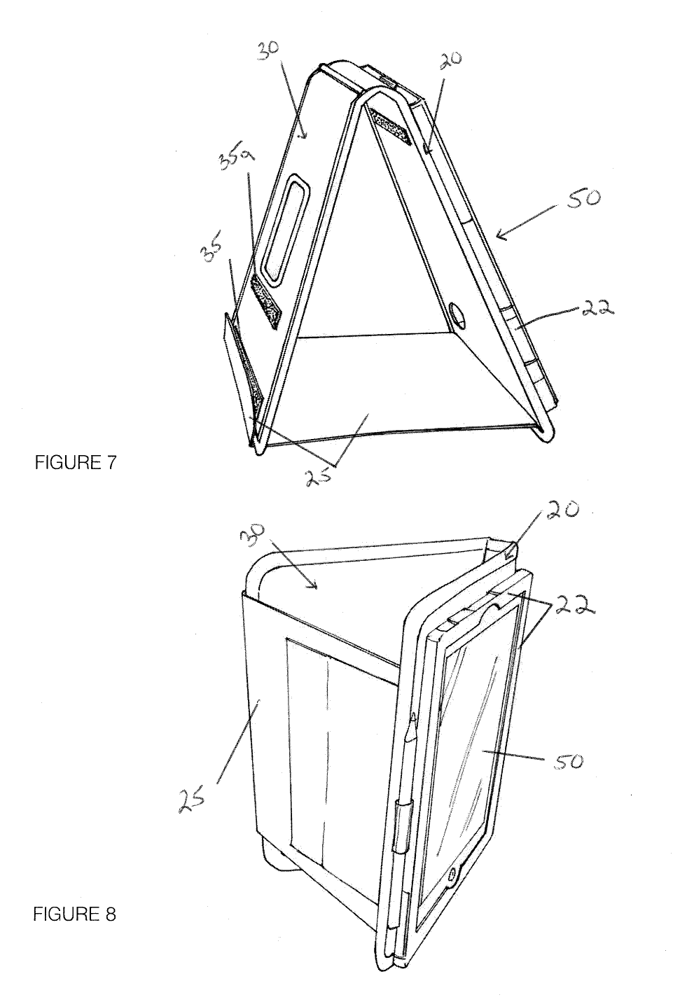

A second “display” mode is shown in FIGS. 7 and 8. In this mode, the longer rigid flap (25) is secured to the perimeter securing mechanism (35), as shown in FIG. 7. In this mode the case remains substantially open, with the rigid flap forming one face of a triangular configuration, with the respective first and second panels (20 and 30) forming the other two faces of the triangle. This allows the case to stand upright in either a landscape display configuration (FIG. 7) or in a portrait display configuration (FIG. 8.)

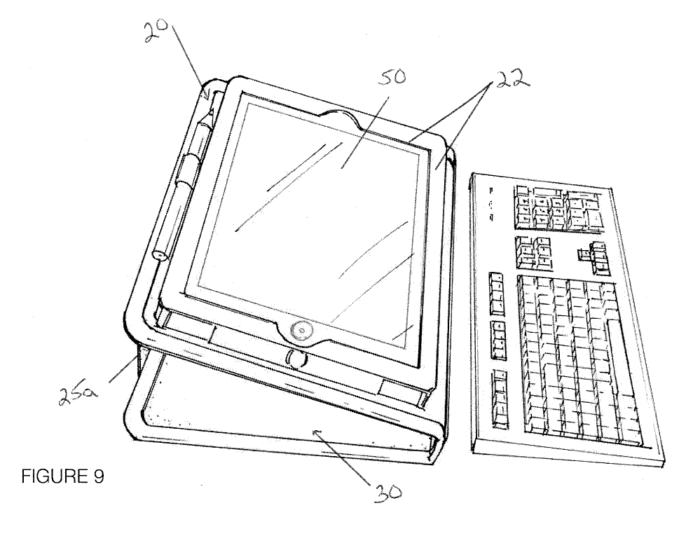

A third “typing” mode is shown in FIG. 9. In this mode, the shorter rigid flap (25a) is secured to the perimeter securing mechanism (35), the case remains held in a slightly open position, as seen in FIG. 9, ideal for a desktop typing display. In this mode, the second panel (30) rests flat on a surface, and first panel (30) is elevated in a slightly angled orientation.

In the first display mode, as shown in FIGS. 4 through 6, the second panel (30) is folded completely back such that the case (10) becomes a support surface with the tablet computer (50) fully exposed. The interior face (31) of second panel (30), has opening (32) adapted to receive a user's hand. In the preferred embodiment, second panel (30), has an additional interior fabric layer (33) comprised of a preferably elastic material, such as elastene or Lycra. The opening (32) is a hole in the elastic layer (33), such that a user's hand can be inserted into the opening (32), and placed between the elastic layer (33) and the interior face (31) of the second panel (30). The additional fabric layer (33) is secured to the interior face (31) at or near the perimeter, such that when a user's hand is inserted inside the opening (32), the user can fully open the hand, extending all fingers outwards to optimize the security and comfort, without interference with any seems or stitching. The user's hand can be inserted from any direction, and this mode allows full mobility of the device. This mode is ideal for on-the-go use as well as sharing and presentation uses, such that others can easily view the screen of the tablet computer while the user manipulates the device.

In the second display mode, as shown in FIGS. 7 and 8, one of the rigid flaps (25) is secured to the securing mechanism (35) such that the rigid flap (25) forms a an additional support surface. In the display mode, the case forms a substantially triangular configuration, allowing the case to stand upright in a display position.

In the third typing mode, as shown in FIG. 9, one of the rigid flaps (25a) is secured to the securing mechanism (35) such that the rigid flap (25a) forms an elevational support brace. In the typing mode, the rigid flap (25a) provides support for one end of the first panel (20), ideal for resting the case on a flat surface while mainlining a slightly angled viewing face for the tablet computer (50).

What is claimed is:

1. A convertible case for a tablet computer comprising a first panel and a second panel, said first and second panel being attached and foldable along an axis,
wherein said first panel is defined by an interior face, said interior face of the first panel adapted to securely hold a tablet computer on the interior face, and said second panel is defined by an interior face, said interior face of the second panel having a fabric layer covering a substantial portion of said interior face, said fabric layer have an opening adapted to receive a user's hand, such that when a user's hand is placed in said opening, the user's hand is snugly held in place between said interior face and said fabric layer;
wherein said first panel and second panel are capable of folding along an axis such that said first and second panels are aligned back-to-back, wherein the interior face of said first panel and the interior face of said second panel are directed outwards in opposite directions.

2. A convertible case for a tablet computer of claim 1, wherein said fabric layer is an elastic material.

3. A convertible case for a tablet computer of claim 1, further comprising at least one semi-rigid support flap;
wherein said first panel is defined by an interior face and an exterior face, said exterior face includes at least one semi-rigid support flap, said support flap having a first and second end, said first end of said support flap securely fixed near the perimeter edge of said exterior face of the first panel, and the second end of said support flap is removably attached to the exterior face using a detachable securing device;
wherein the interior face of said second panel further comprises a securing device compatible with the detachable securing device at the second end of the support flap, such that when the first and second panels are folded along the axis, the second end of the support flap can be removably attached to the securing device on the interior face of said second panel, forming a generally triangular structure, wherein the three sides of the triangle are defined by the first panel, second panel, and support flap respectively.

4. A convertible case for a tablet computer of claim 3, comprising at least two rigid support flaps, said flaps each having a different length as measured between the first and second ends of said flaps.
